(19) United States
(12) Patent Application Publication
(10) Pub. No.: US 2023/0371222 A1
(43) Pub. Date: Nov. 16, 2023

(54) AUTOMATIC FEEDER ARRANGEMENT SUPPORT SYSTEM AND AUTOMATIC FEEDER ARRANGEMENT SUPPORT PROGRAM

(71) Applicant: YAMAHA HATSUDOKI KABUSHIKI KAISHA, Iwata-shi, Shizuoka (JP)

(72) Inventors: Yoichi MATSUSHITA, Iwata-shi, Shizuoka (JP); Yoshihiro OTAKA, Iwata-shi, Shizuoka (JP)

(73) Assignee: YAMAHA HATSUDOKI KABUSHIKI KAISHA, Iwata-shi, Shizuoka (JP)

(21) Appl. No.: 18/246,021

(22) PCT Filed: Oct. 14, 2020
(86) PCT No.: PCT/JP2020/038741

§ 371 Date: Mar. 20, 2023

(51) Int. Cl. H05K 13/08; H05K 13/02

(52) U.S. Cl. CPC H05K 13/085; H05K 13/086; H05K 13/02

(57) ABSTRACT

An automatic feeder arrangement support system is in a component mounting line including a component mounting device that includes a component supply device and a mounting head configured to pick up components from component supply tapes and mount the components on a substrate. The automatic feeder arrangement support system includes a component shortage time calculation section and a component shortage detection section. The component shortage time calculation section is configured to calculate component shortage time data based on production plan data and substrate data related to substrate. The component shortage detection section is configured to perform a simulation and detect whether component shortage occurs or not based on the component shortage time data and workable time data for a replenishment work of manual feeders.

### CROSS-REFERENCE TO RELATED APPLICATION

This application is a National Stage of International Patent Application No. PCT/JP2020/038741, filed Oct. 14, 2020, the entire content of which is incorporated herein by reference.

### BACKGROUND

### Technical Field

The technology described herein relates to an automatic feeder arrangement support system and an automatic feeder arrangement support program.

### Background Art

A component mounting line in which components are mounted on substrates to produce mounted substrates includes component mounting devices that are connected to each other. In each of the component mounting devices, the component mounting operation is performed repeatedly. In the component mounting operation, the components are picked up from the parts feeder that is installed in the component supply section and transferred to and mounted on the substrate. In the process of successively performing the component mounting operation, the component replenishment operation of replenishing new components to the parts feeder is performed repeatedly at the timing when component shortage is caused by consuming the components.

To perform the component replenishment operation at the suitable timing, a countermeasure such as notification of occurrence time of the component shortage that is predicted in advance by performing simulation calculation is used. If a large number of parts feeder are close to the component shortage time and the component replenishment operation is started after the display of “normal warning”, the component shortage may occur in the parts feeder before finishing the replenishment operation.

In the component replenishment support method described in Japanese Unexamined Patent Publication No. 2016-225385, warning consideration start time is set as the time for starting to consider whether or not to perform the display of “early warning” for prompting the early component replenishment to the parts feeder precedent to “normal warning” or the display of the warning of “man-hour lack” for prompting a support call of the worker. The target feeder selector selects parts feeder of which component shortage time is between the warning start time and warning consideration start time as a selection feeder that is to be a consideration target of the warning of “early warning” or “man-hour lack”.

### SUMMARY

In the above-described component replenishment support method, the component shortage time is predicted by simulating the splicing in the manual feeder. In the splicing in the manual feeder, with a splicing tape, a new component supply tape is connected to a trailing end of the component supply tape from which components are currently supplied. The splicing requires technique to perform replenishment. Therefore, the line may be stopped because of human errors and this may lower production efficiency. To deal with such a problem, automatic feeders have been developed. With the automatic feeders, the replenishment can be automated by automatically loading new component supply tapes. The work efficiency can be increased (the work time can be shortened) by the introduction of the automatic feeders; however, the automatic feeders are not effectively used in planning works (optimized arrangement of automatic feeders).

An automatic feeder arrangement support system according to this discloser is in a component mounting line including a component mounting device that includes a component supply device and a mounting head. Automatic feeders and manual feeders can be set to the component supply device. In the automatic feeders, component supply tapes with components are preset, respectively, and the automatic feeders replenish the component supply tapes at a same time when the component supply tapes currently used have no component. The manual feeders perform replenishment by connecting the component supply tapes to ends of the component supply tapes currently used. The mounting head is configured to pick up the components from the component supply tapes and mount the components on a substrate. The automatic feeder arrangement support system includes a component shortage time calculation section configured to calculate component shortage time data based on production plan data and substrate data, and a component shortage detection section configured to perform a simulation and detect whether component shortage occurs or not based on the component shortage time and workable time data for a replenishment work of the manual feeders.

According to the technology described herein, planning of operations can be achieved by introducing automatic feeders.

### BRIEF DESCRIPTION OF THE DRAWINGS

FIG. 1 is a view illustrating a whole configuration of a component mounting line;

FIG. 2 is a plan view of the component mounting device;

FIG. 3 is an elevation view of the component mounting device;

FIG. 4 is a side view of an automatic feeder;

FIG. 5 is a magnified side view of a rear feeding section of the automatic feeder;

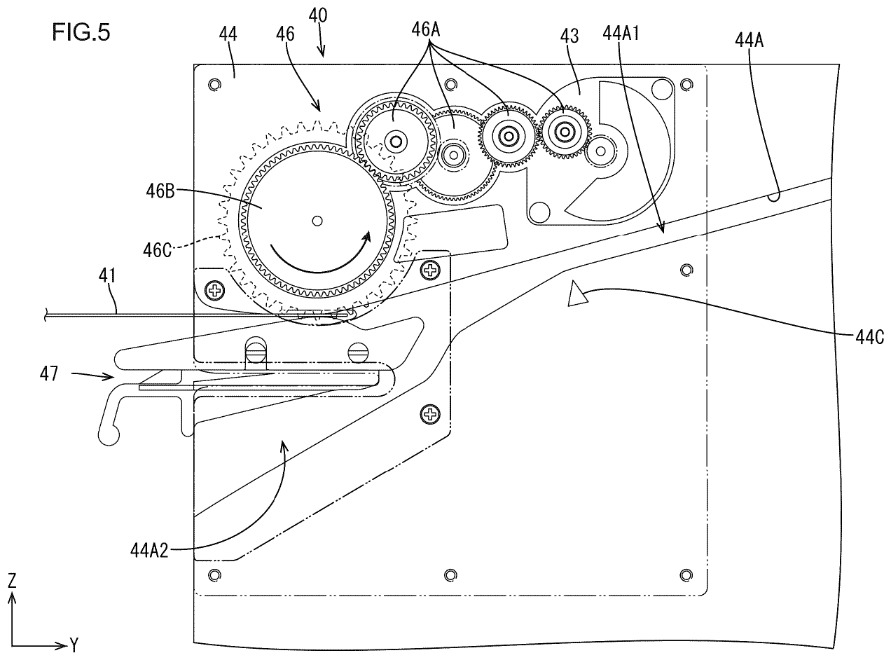

FIG. 6 is a perspective view illustrating a support mode (1) of supporting a component supply tape according to attachment and detachment of a clamp member;

FIG. 7 is a perspective view illustrating a support mode (2) of supporting the component supply tape according to attachment and detachment of the clamp member;

FIG. 8 is a block diagram illustrating an electric configuration of the component mounting device;

FIG. 9 is a block diagram illustrating an electric configuration of a management server;

FIG. 10A is a table representing the number of substrate A to be produced and components to be used, and FIG. 10B is a table representing feeders used for the substrate A and the remaining number of components;

FIG. 11 illustrates a component shortage timing chart;

FIG. 12A illustrates a simulation in which workable time is included in the component shortage timing chart to check whether component shortage occurs or not, and FIG. 12B illustrates a simulation performed again to check whether component shortage occurs or not when the manual feeder in which component shortage is supposed to occur in FIG. 12A is replaced with an automatic feeder;

FIGS. 13A and 13B illustrate references for specifying a component type for which the AF is used according to the first embodiment;

FIG. 14 is a flowchart of the simulation according to the first embodiment;

FIG. 15 is a flowchart of detecting component shortage in the replenishment;

FIG. 16 is a flowchart of specifying a component type for which the AF is used to avoid component shortage;

FIG. 17 illustrates references for specifying a component type for which the AF is used according to a second embodiment;

FIG. 18 illustrates references for specifying a component type for which the AF is used with reference to using speed;

FIG. 19 illustrates one example of a display screen displaying using status of AFs;

FIG. 20 is a flowchart of the simulation according to the second embodiment;

FIG. 21 is a flowchart of specifying a component type for which the AF is used to avoid component shortage;

FIG. 22 is a table illustrating a list of components stored in an automated storage according to a third embodiment; and

FIG. 23 is a flowchart of a simulation according to a third embodiment.

### DETAILED DESCRIPTION

### Description of Embodiments According to the Present Disclosure

First, embodiments according to the present disclosure will be listed and described.

(1) An automatic feeder arrangement support system according to this discloser is in a component mounting line including a component mounting device that includes a component supply device and a mounting head. Automatic feeders and manual feeders can be set to the component supply device. In the automatic feeders, component supply tapes with components are preset, respectively, and the automatic feeders replenish the component supply tapes at a same time when the component supply tapes currently used have no component. The manual feeders perform replenishment by connecting the component supply tapes to ends of the component supply tapes currently used. The mounting head is configured to pick up the components from the component supply tapes and mount the components on a substrate. The automatic feeder arrangement support system includes a component shortage time calculation section configured to calculate component shortage time data based on production plan data and substrate data and a component shortage detection section configured to perform a simulation and detect whether component shortage occurs or not based on the component shortage time and workable time data for a replenishment work of the manual feeders.

In the above system, one of the manual feeders is defined as a target to be replaced with one of the automatic feeders such that component shortage is not detected by the component shortage detection section by replacing the one of the manual feeders with the one of the automatic feeders. The automatic feeders are set such that no component shortage is detected. Therefore, the component shortage is previously avoided and the planning of operations, which is a merit of introduction of the automatic feeders, can be achieved.

(2) In the above system, when the component shortage detection section detects component shortage, the component shortage detection section may perform a simulation again detect whether component shortage occurs if the one of the manual feeders is replaced with the one of the automatic feeders.

The component shortage time data is calculated by the component shortage time calculation section and the simulation is performed and the component shortage detection section detects whether component shortage occurs or not. If component shortage is detected, the manual feeder is replaced with the automatic feeder. Then, the simulation is performed again and the component shortage detection section detects whether component shortage occurs or not.

(3) The one of the manual feeders in which component shortage is detected by the component shortage detection section may be defined as a target to be replaced with the one of the automatic feeders. Accordingly, component shortage can be surely avoided.

(4) Another one of the manual feeders that is related to the one of manual feeders in which the component shortage is detected by the component shortage detection section may be defined as a target that is to be replaced with another one of the automatic feeders. Another one of the manual feeders that is related to the one of manual feeders in which the component shortage is detected by the component shortage detection section means that another one of the manual feeders is not necessarily the one in which component shortage is detected and it does not matter whether the another one of the manual feeders is the one in which the component shortage is detected by the component shortage detection section or not. The another one of the manual feeders includes other manual feeders included in a specified rush, which will be described later. For example, the automatic feeder can be used for the components that are effective in avoiding the component shortage.

(5) The one of manual feeders in which the component shortage is detected by the component shortage detection section and another one of the manual feeders that is related to the one of manual feeders may be defined as targets that are to be replaced with the automatic feeders. The manual feeders to be replaced with the automatic feeders are narrowed to the manual feeder in which the component shortage is detected by the component shortage detection section and the related manual feeder.

(6) The system may further include a rush detection section configured to perform a simulation and detect whether a rush occurs. In the replenishment of the manual feeders, a time period in which adjacent workable times overlap or a time period in which workable time and time for a work other than the replenishment of the manual feeders overlap may be defined as the rush. Another one of the manual feeders that is included in the rush including the one of the manual feeders in which component shortage is detected by the component shortage detection section may be defined as a target that is to be replaced with another one of the automatic feeders. Therefore, the arrangement of the automatic feeders can be determined based on the rush.

(7) A continuous time period in which the workable time of the one of the manual feeders in which component shortage is detected by the component shortage detecting section and workable time of another one of the manual feeders that is continuous to the past from the workable time of the one of the manual feeders overlap may be defined as a specified rush. The rush detection section may be configured to detect the specified rush. The other one of the manual feeders included in the specified rush may be defined as a target to be replaced with another one of the automatic feeders. The manual feeders that are to be replaced with the automatic feeders can be narrowed to another manual feeders included in the specified rush.

(8) With multiple rushes including the rush being caused during the production plan, one of the manual feeders that is involved in the multiple rushes for a greatest number of times may be defined as a target to be replaced with one of the automatic feeders. The manual feeder that is involved in the rush for the greatest number of times is determined as the one that is to be replaced with the automatic feeder.

(9) A combination of the manual feeders that are to be replaced with the automatic feeders may be determined among the manual feeders that are defined as targets to be replaced by operations repeatedly performed by the automatic feeder arrangement support system. Accordingly, a combination of the manual feeders that are to be replaced with the automatic feeders can be determined.

(10) The rush detection section may be configured to perform a simulation with reference to unworkable time and detect whether the rush in which component shortage occurs is caused or not. Accordingly, it can be detected whether the rush in which component shortage occurs is caused or not with reference to unworkable time.

(11) The one of the manual feeders to be replaced with the one of the automatic feeders may be displayed on a display section. Accordingly, it can be confirmed with the display section which one of the manual feeders is to be replaced.

(12) The display section may display the one of the manual feeders to be replaced with the one of the automatic feeders and a due date of replacement. Accordingly, it can be confirmed with the display section which one of the manual feeders should be replaced and until when the manual feeder should be replaced.

(13) The component shortage detection section may obtain information from the component mounting device during production and periodically perform a simulation to detect whether component shortage occurs. Accordingly, the arrangement of the automatic feeders can be determined according to the actual production status.

(14) One of the automatic feeders whose number of times to be used is equal to a setting value or smaller may be defined as a target to be replaced. Accordingly, the automatic feeders can be effectively used.

(15) A simulation may be performed with using an actual remaining number of components in the replenishment. Accordingly, component shortage can be detected according to the actual remaining number of components.

(16) Another aspect of this disclosure is related to a program for supporting arrangement of automatic feeders in a component mounting line including a component mounting device that includes a component supply device and a mounting head. The automatic feeders and manual feeders can be set in the component supply device. In the automatic feeders, component supply tapes with components are preset, respectively, and the automatic feeders replenish the component supply tapes at a same time when the component supply tapes currently used have no component. The manual feeders perform replenishment by connecting the component supply tapes to ends of the component supply tapes currently used. The mounting head is configured to pick up the components from the component supply tapes and mount the components on a substrate. The program causes a computer to calculate component shortage time data based on production plan data and substrate data, perform a simulation and detect whether component shortage occurs or not based on the component shortage time and workable time data for a replenishment work of the manual feeders, and define one of the manual feeders as a target to be replaced with one of the automatic feeders such that component shortage is not detected by the component shortage detection section by replacing the one of the manual feeders with the one of the automatic feeders.

### Details of First Embodiment of the Present Disclosure

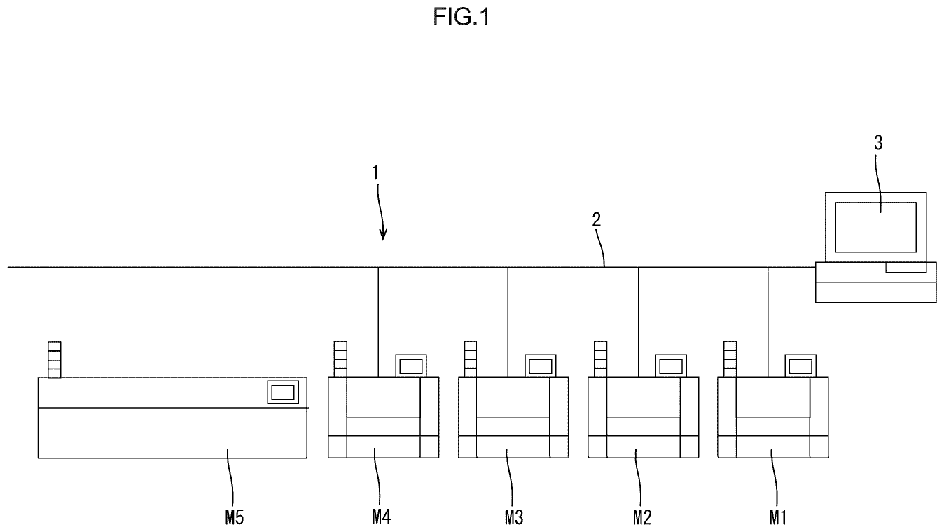

One embodiment of an automatic feeder arrangement support system 10 for arranging automatic feeders in a component mounting line according to the present disclosure will be described with reference to drawings. The present disclosure is not limited to the embodiments but all modifications within and equivalent to the technical scope of the claimed disclosure may be included in the technical scope of the present technology. In FIG. 1, a component mounting line 1 is for mounting components on substrates and producing mounted substrates. A printing device (not illustrated), component mounting devices M1 to M4, and a reflow furnace M5 are connected to each other with a local area network (LAN) 2 and a management server 3 controls them.

Each of the component mounting devices M1 to M4 picks up components E from feeders 16 that are arranged in a component supply device and transfers the components E to a substrate B with a component mounting unit 20. This operation is a component mounting operation. Then, the substrate B on which the components E are mounted is transferred to the reflow furnace M5 and the components E mounted on the substrate B are bonded with soldering and a mounted substrate is produced. Thus, the component mounting line 1 includes the component mounting devices M1 to M4 that pick up the components E that are supplied from each feeder 16 and mount the components E on the substrate B.

<Whole Configuration of Component Mounting Device>

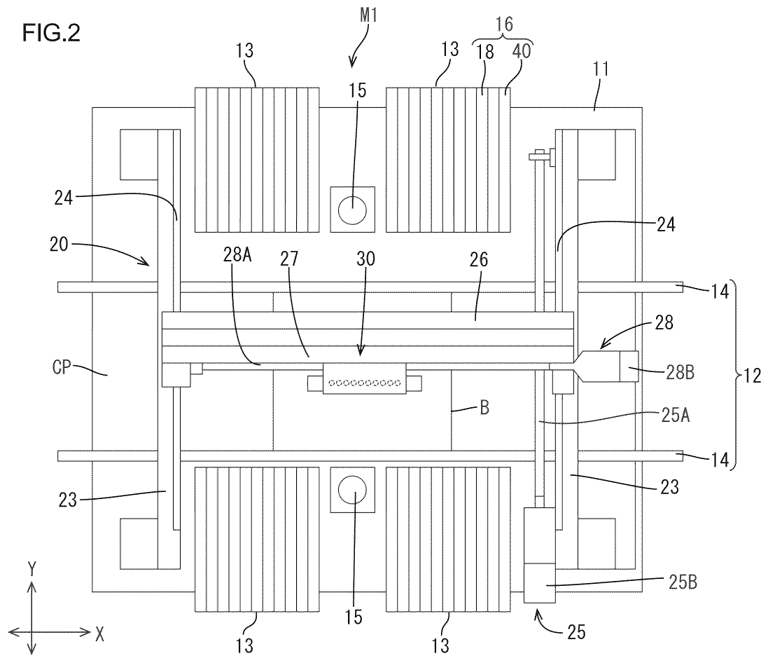

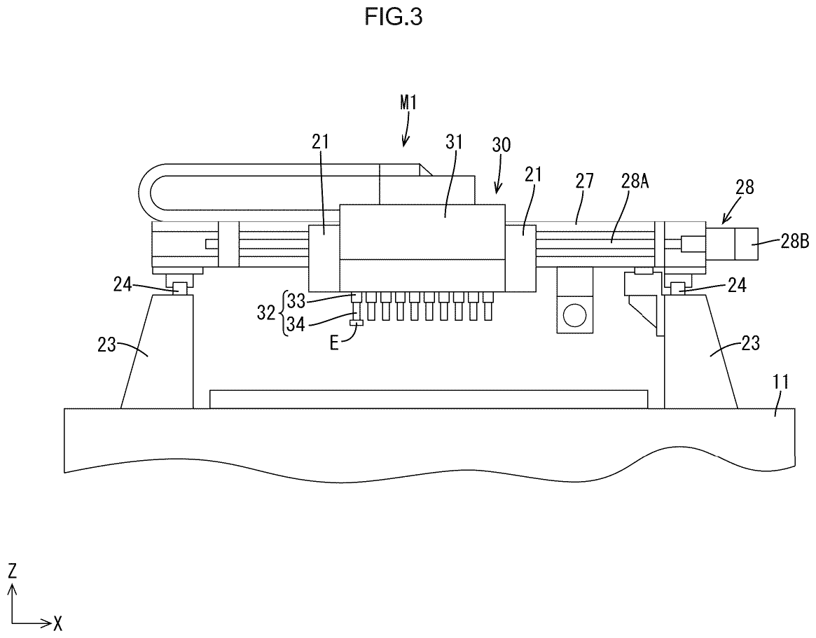

Next, a configuration of the component mounting devices M1 to M4 will be described with reference to FIGS. 2 and 3. The component mounting devices M1 to M4 have a same configuration and the component mounting device M1 will be described. The component mounting device M1 includes a base 11 having a rectangular plan view shape, a transfer device 12 transferring the substrate B, a component mounting unit 20 mounting the components on the substrate B, and component supply devices 13 supplying the components E to the component mounting unit 20.

In the following description, an X-direction corresponds to the right-left direction (a transfer direction of the substrate B) in FIG. 2 and may be referred to as the right-left direction. An Y-direction corresponds to an upper-bottom direction (a direction perpendicular to the transfer direction of the substrate B) in FIG. 2 and may be referred to a front-rear direction. The lower side in the drawing corresponds to a front side and an upper side in the drawing corresponds to a rear side. A Z-direction corresponds to an upper-bottom direction in FIG. 3 and may be referred to as the upper-bottom direction.

<Base>

As illustrated in FIG. 2, the base 11 has a substantially rectangular plan view shape that is elongated in the right-left direction and has an upper surface that is parallel to an X-Y plane surface extending in the X-direction and the Y-direction. The transfer device 12 that extends in the right-left direction and the component mounting unit 20 are arranged on the upper surface of the base 11.

<Transfer Device>

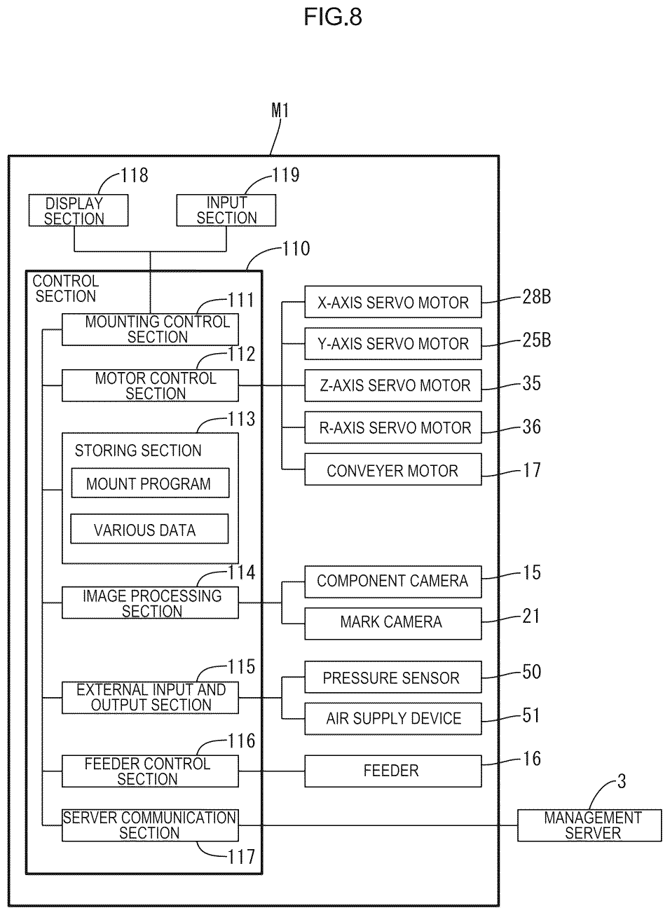

As illustrated in FIGS. 2 and 3, the transfer device 12 includes a pair of conveyer belts 14 that move in the right-left direction in a circulation manner. The transfer device 12 transfers the substrate B along a transfer section CP. The conveyer belts 14 are driven by a conveyer motor 17 (refer to FIG. 8) in a circulation manner. The substrate B is transferred by the pair of conveyer belts 14 from an upstream side to a mounting position. After the components E are mounted on the substrate B at the mounting position, the substrate B is transferred toward a downstream side by the pair of conveyer belts 14. Accordingly, the substrate B is transferred from the upstream side to the downstream side along the transfer section CP.

<Component Mounting Unit>

The component mounting unit 20 is for picking up the components E that are supplied from the feeders 16 of the component supply devices 13 and mounting the components E on the substrates B. As illustrated in FIG. 2, the component mounting unit 20 includes a pair of Y-axis frames 23, an X-axis frame 26, the head unit 30, an X-axis movement device 28, and a Y-axis movement device 25. The Y-axis frames 23 are disposed near the respective right and left edges of the base 11. The head unit 30 is movably mounted on the X-axis frame 26.

The Y-axis movement device 25 includes a Y-axis ball screw shaft 25A, ball nuts that are mounted on the Y-axis ball screw shaft 25A and not illustrated, and a Y-axis servo motor 25B. A pair of Y-axis guide rails 24 that extend in the Y-direction is mounted on the pair of Y-axis frames 23. The Y-axis ball screw shaft 25A extends in the Y-direction. The Y-axis servo motor 25B is mounted on an edge of the Y-axis ball screw shaft 25A. According to the control of a current flow to the Y-axis servo motor 25B, the X-axis frame 26 and the head unit 30 that is fixed to the X-axis frame 26 move along the pair of Y-axis guide rails 24 in the front-rear direction.

The X-axis movement device 28 includes an X-axis ball screw shaft 28A, ball nuts that are mounted on the X-axis ball screw shaft 28A and not illustrated, and a Y-axis servo motor 28B. As illustrated in FIG. 3, the X-axis ball screw shaft 28A that extends in the X-direction and an X-axis guide rail 27 that extends in the X-direction are mounted on the X-axis frame 26. The X-axis servo motor 28B is mounted on an edge of the X-axis ball screw shaft 28A. According to the control of a current flow to the X-axis servo motor 28B, the head unit 30 moves along the X-axis guide rail 27 in the right-left direction.

<Head Unit>

As illustrated in FIGS. 2 and 3, the head unit 30 includes a head unit body 31 that has a box shape and mounting heads 32 for mounting the components E.

The mounting heads 32 are arranged in the right-left direction with projecting downward from the head unit body 31. Each of the mounting heads 32 includes a shaft 33 that extends in the upper-bottom direction and a suction nozzle 34 that is detachably attached to a lower end of the shaft 33.

A Z-axis servo motor 35 and an R-axis servo motor 36 that are mounted in the head unit body 31 are connected to the shaft 33. Each of the shafts 33 can move up and down in the upper-bottom direction by the Z-axis servo motor 53 and can revolve on a shaft by the R-axis servo motor 36.

As illustrated in FIG. 3, each of the suction nozzles 34 has an almost cylindrical shape that extends in the upper-bottom direction. Each of the suction nozzles 34 is detachably attached to the lower end of the shaft 33 with an upper end of the suction nozzle 34 being held by a holding portion, which is not illustrated, of the lower end of the shaft 33. Each of the mounting heads 32 is supplied with negative pressure from an air supply device 51 and this allows the suction nozzle 34 to have suction force at an end thereof.

As illustrated in FIG. 3, a pair of mark cameras 21 is mounted on two side surfaces of the head unit body 31, respectively. The mark cameras 21 take images of fiducial marks on the substrates B to recognize the substrate B with the images. A pair of component cameras 15 is disposed on front and rear sides with respect to the substrate B on the base 11. The component cameras 15 take an image of the component E that is held and suctioned by the mounting head 32 of the head unit 30.

<Component Supply Device>

As illustrated in FIG. 2, the component supply device 13 includes the feeders 16 and two component supply devices 13, which are arranged in the right-left direction, are disposed on each of the front and rear sides with respect to the transfer device 12. The component supply device 13 is disposed at four positions. The feeders 16 include manual feeders 18 and automatic feeders 40 that are arranged in the right-left direction. The manual feeder 18 includes an electric feeding device (not illustrated), which pulls the component supply tape from the reel, and supplies the components E one by one from an end portion close to the transfer device 12. The component supply tape holds the components E at equal intervals on a tape.

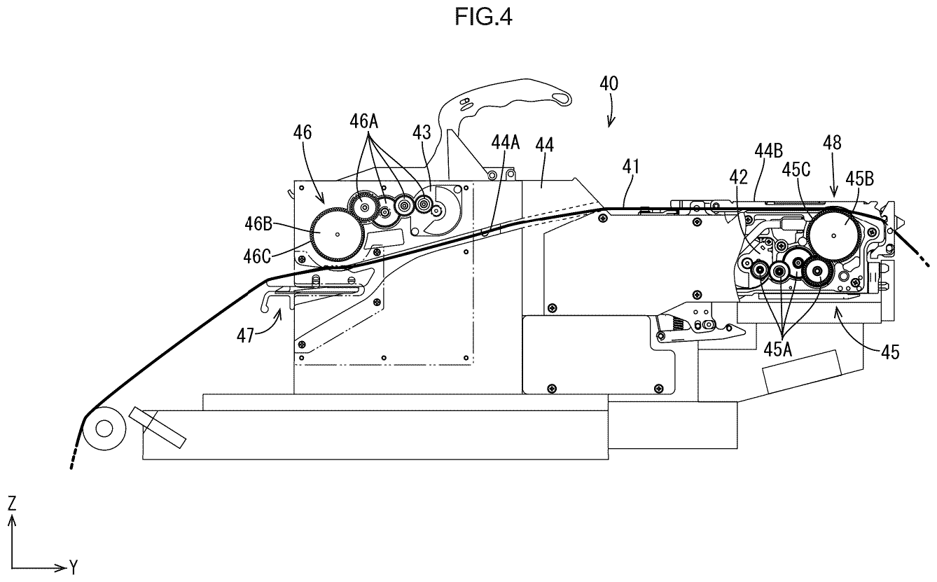

As illustrated in FIG. 4, the automatic feeder 40 includes a component supply tape 41 that is fed frontward by a driving shaft motor 42 and the components E held by the tape are sequentially supplied. If it is determined that there is shortage of components regarding the component E that is held, a preset component supply tape 41 for replacement is loaded by a loading shaft motor 43. The driving shaft motor 42 and the loading shaft motor 43 are controlled based on the signals from a feeder control section 116.

The automatic feeders 40 are feeders (may be referred to as AF) that automatically perform loading. As illustrated in FIG. 4, the automatic feeder 40 includes a body section 44, a front-side feeding section 45, a rear-side feeding section 46, a tape cavity 44A, a tape guide 44B, a tape sensor 44C, a feeder control section 116, and a clamp member 47. The body section 44 has an elongated shape extending in the front-rear direction (the right-left direction in FIG. 4). The front-side feeding section 45 is disposed in a front side portion of the body section 44 and the rear-side feeding section 46 is disposed in a rear side portion of the body section 44. The clamp member 47 is detachably disposed in the rear-side end portion of the body section 44. The body section 44 is made with aluminum die casting, for example.

The front-side feeding section 45 includes the driving shaft motor 42, front-side gears 45A, and a front-side sprocket 45B that is disposed in a front end upper portion of the body section 44. The front-side gears 45A transmit power from the driving shaft motor 42 and rotate the front-side sprocket 45B. The front-side sprocket 45B has teeth 45C on the outer periphery thereof at equal intervals. The teeth 45C are fitted in fit holes of the component supply tape 41. The front-side feeding section 45 rotates the front-side sprocket 45B with the teeth 45C of the front-side sprocket 45B being meshed with the fit holes of the component supply tape 41 to feed the component supply tape 41 to feed the component supply tape 41 from the rear-side feeding section 46 to a component supply position 48 that is disposed in a front end section of the automatic feeder 40.

The rear-side feeding section 46 includes the loading shaft motor 43, rear-side gears 46A, and a rear-side sprocket 46B that is disposed in a rear end upper portion of the body section 44. The rear-side gears 46A transmit power from the loading shaft motor 43 and rotate the rear-side sprocket 46B. The rear-side sprocket 46B has teeth 46C on the outer periphery thereof at equal intervals. The teeth 46C are fitted in fit holes of the component supply tape 41.

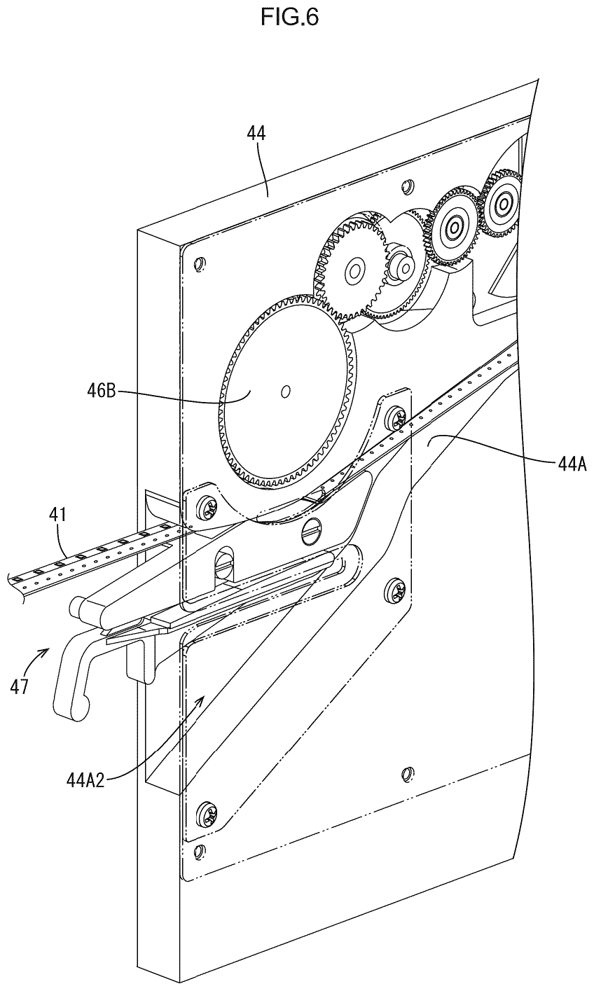

The tape cavity 44A is a cavity along which the component supply tape 41 is transferred. The tape cavity 44A extends through the rear portion of the body section 44 in the front-rear direction. The tape cavity 44A extends obliquely upward from the rear end portion of the body section 44 toward a front portion of the body section 44. As illustrated in FIG. 6, the tape cavity 44A includes a front-side cavity 44A1 in a front portion thereof and a rear-side cavity 44A2 in a rear portion thereof. The front-side cavity 44A1 is elongated and narrow. The rear-side cavity 44A2 extends in a wide range in the upper-down direction from an end of the front-side cavity 44A1 toward the rear end portion of the body section 44. In each of the automatic feeder 40, the component supply tape 41 pulled from the reel enters the tape cavity 44A from the rear end portion of the body section 44 and exits the tape cavity 44A in the front portion of the body section 44 and is disposed on an upper surface of the body section 44.

Next, a method of supplying components with the automatic feeder 40 will be described. As a preparation operation, an operator attaches the clamp member 47 to the body section 44 of the automatic feeder 40 and engages the distal end of the present component supply tape 41 extending from the reel to the rear-side sprocket 46B as illustrated in FIG. 6. Thereafter, by rotating the rear-side sprocket 46B, the component supply tape 41 is fed until the distal end thereof is moved to the front portion of the automatic feeder 40 and a leading end portion of the component supply tape 41 is mated to the front-side sprocket 45B.

The component supply operation is performed by the feeder control section 116 according to a mounting program after the above preparation operation is finished. In the component supply operation, the feeder control section 116 drives the driving shaft motor 42 to rotate the front-side sprocket 45B and feeds the component supply tape 41 to the component supply position 48. The rear-side sprocket 46B is configured to idle. The present component supply tape 41 can be fed by rotating only the front-side sprocket 45B without driving the loading shaft motor 43.

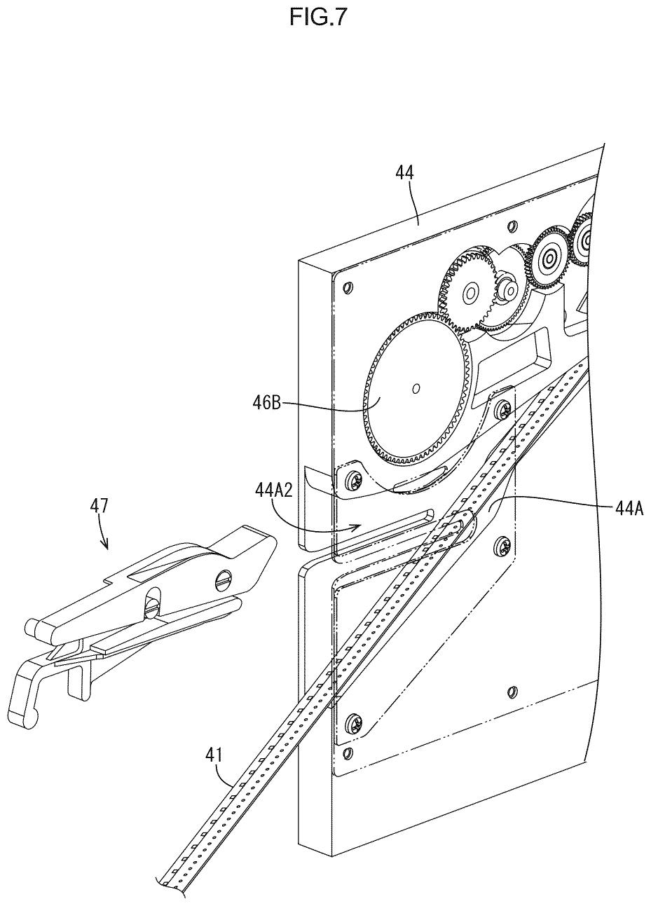

Next, the operator detaches the clamp member 47 from the body section 44 with the current component supply tape 41 being fed to the component supply position 48. As a result, as illustrated in FIG. 7, the portion of the current component supply tape 41 that is supported by the clamp member 47 drops by its own weight and is separated from the rear-side sprocket 46B. The current component supply tape 41 is already mated to the front-side sprocket 45B. Therefore, even if the current component supply tape 41 is separated from the rear-side sprocket 46B, the current component supply tape 41 can be fed to the component supply position 48 by rotating the front-side sprocket 45B.

Next, the clamp member 47 is attached to the body section 44 of the automatic feeder 40 again and a leading end portion of a subsequent component supply tape 41 is disposed between the clamp member 47 and the rear-side sprocket 46B to be mated to the rear-side sprocket 46B. Thus, the subsequent component supply tape 41 can be preset in the body section 44 before occurrence of the component shortage in the current component supply tape 41.

Then, when a trailing end of the current component supply tape 41 passes the front-side cavity 44A1 of the tape cavity 44A and the tape sensor 44C detects no component supply tape 41 in the front-side cavity 44A1, the feeder control section 116 receives the detection signal and drives the loading shaft motor 43 to rotate the rear-side sprocket 46B. Accordingly, the leading end of the subsequent component supply tape 41 is moved to the front section of the automatic feeder 40 and mated to the front-side sprocket 45B. Thus, the switching from the current component supply tape 41 to the subsequent component supply tape 41 is performed without detaching the automatic feeder 40. Namely, the loading of the subsequent component supply tape 41 can be performed automatically.

<Automatic Feeder Arrangement Support System>

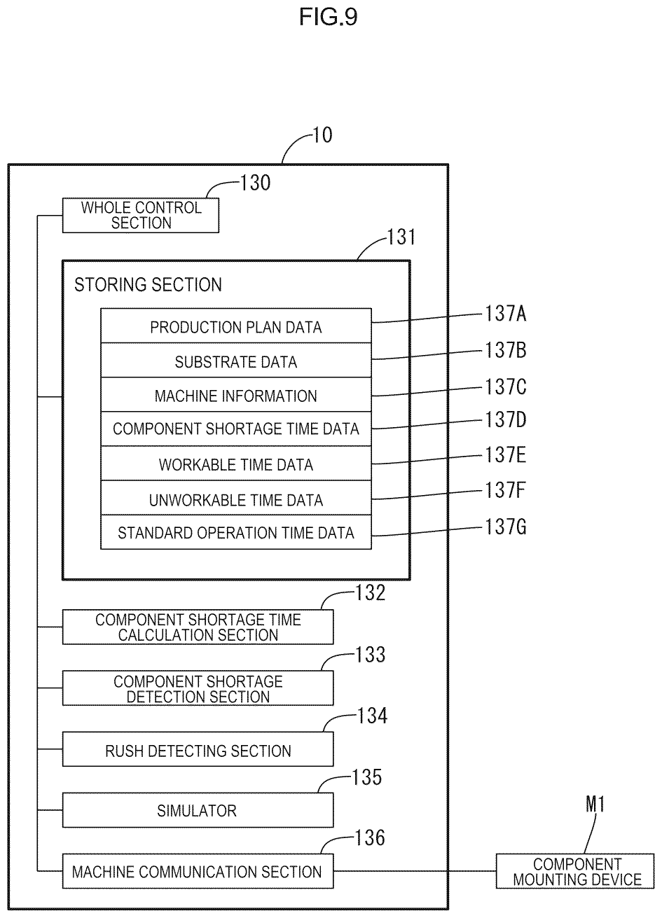

Next, an electric configuration of the automatic feeder arrangement support system 10 will be described with reference to FIGS. 8 and 9. The automatic feeder arrangement support system 10 of this embodiment includes the component mounting device M1 and the management server 3.

The component mounting device M1 is controlled by a control section 110 as a whole. The control section 110 includes a mounting control section 111 including a central processing unit (CPU). The mounting control section 111 is connected to a motor control section 112, a storing section 113, an image processing section 114, an external input and output section 115, the feeder control section 116, a server communication section 117, a display section 118, and an input section 119.

The motor control section 112 controls the Y-axis servo motor 25B, the Z-axis servo motor 35, the R-axis servo motor 36, and the conveyer motor 17 according to the instruction from the mounting control section 111 to mount the components E.

The storing section 113 stores mount programs for mounting the components E on the substrates B and various kinds of data. The various kinds of data include substrate information related to the size of the substrates B that are scheduled to be produced and the feeding speed, identification information of the shafts 33 and suction nozzles 34 that are mounted in the head unit 30, the positions of the components E that are measured by the cameras 15, 21, and the reference position for determining position deviation of the component E.

The image processing section 114 is configured to receive image signals output from the mark camera 21 and the component cameras 15 and create an image based on the received image signals. The image processing section 114 is configured to recognize the image of the fiducial mark on the substrate B that is taken by the mark camera 21. Accordingly, the position of the substrate B is detected. The image processing section 114 is configured to recognize the image of the component E that is taken by the component cameras 15. Accordingly, the posture of the component E that is suctioned and the deviation of the suctioned position are detected. When the mounting head 32 mounts the components E, the mount position is corrected based on the recognition results.

The external input and output section 115 is a so-called interface. The mounting control section 111 receives the detection signals from the pressure sensor 50 via the external input and output section 115 and send control signals to the air supply device 51. The pressure sensor 50 may be connected to the external input and output section 115 with or without wires.

The feeder control section 116 is connected to the feeders 16 and controls each of the feeders 16. The server communication section 117 is connected to the management server 3 and transfers to and receives from the management server.

The display section 118 is a display device such as a touch panel and a liquid crystal monitor. The display section 118 displays certain items that are necessary to be informed of the operator. The input section 119 is an input device such as a touch panel, a keyboard, and a mouse. The input section 119 performs inputting operations of inputting data and operation commands.

Examples of informing with the display section 118 include warning of information that specifies the feeder 16 in which the component shortage is predicted to occur and the time Ts when the predicted component shortage is caused and warning that man-hour lack is predicted due to a large amount of work that cannot be done even by performing the component replenishment operation properly. Each of the sections is connected to the management server 3 via the server communication section 117, which is the interface, and the LAN 2. This enables transfer of the control signals between the component mounting device M1 and the management server 3.

The management server 3 illustrated in FIG. 9 includes a whole control section 130, a storing section 131, a component shortage time calculation section 132, a component shortage detecting section 133, a rush detecting section 134, a simulator 135, and a machine communication section 136. The whole control section 130 controls and manages each of the devices included in the component mounting line 1 based on the data stored in the storing section 131.

The storing section 131 stores production plan data 137A, substrate data 137B, machine information 137C, component shortage time data 137D, workable time data 137E, unworkable time data 137F, and standard operation time data 137G. The production plan data 137A is related to the types and the number of products that are to be produced in each component mounting line 1. The substrate data 137B is a component table and represents the components and the number of the components that are used for one substrate.

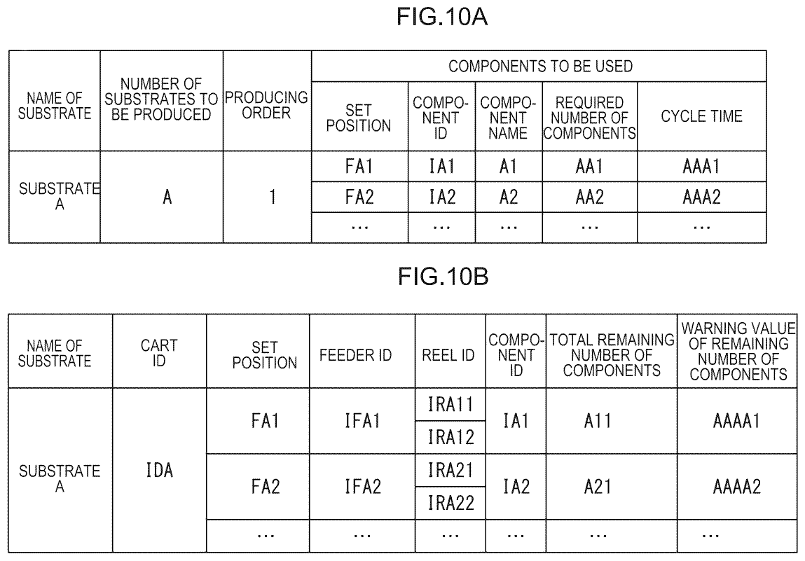

The data illustrated in FIG. 10A is obtained by integrating the production plan data 137A and the substrate data 137B. Namely, data representing the name of substrate, the number of substrates to be produced, the producing order, the set position at which the component to be used s set, the component ID, the number of components needed, and cycle time is obtained.

The machine information 137C is data related to the working condition of the component mounting device M1, the component that is set in the feeder 16, the feeder 16 that is to be used, and the remaining number of components E and such data is illustrated in FIG. 10B. Specifically, the machine information includes the name of substrate, the cart ID, the set position, the feeder ID, the reel ID, the component ID, the total remaining number of components, and the warning value of the remaining number of components. For example, for the substrates A, the cart (IDA) is set in the component supply device 13, the feeders 16 (IFA1, IFA2 . . . ) are set at the set positions (FA1, FA2 . . . ), respectively, the two reels (IRA11, IRA12) are installed in the feeder 16 (IFA1), the components E of the reels (IRA11, IRA12) are the components E (IA1) of the same type, the remaining number of the components E (IA1) is A11, and the warning value of the remaining number of components is AAAA1. Each of the feeders 16 (IFA1, IFA2) includes the two reels (IRA11, IRA12) and therefore the feeders 16 (IFA1, IFA2) are the automatic feeders 40.

The component shortage time data 137D represents time when the component supply tape that is set in the reel has no components E (short of the components E). The workable time data 137E represents time from the warning of the remaining number of components to the component shortage (short of the components E). The standard operation time data 137G represents standard time that is necessary for the replenishment operation.

The component shortage time calculation section 132 is configured to calculate the timing when the component shortage occurs during the production plan, that is, the component shortage time representing time when the component shortage occurs. The calculation method is subtracting “the number of components used for producing one substrate” from “the remaining number of components that are currently installed in the machine” (formula 1). The calculation of the formula 1 is performed repeatedly and if the remaining number of components becomes insufficient, the component shortage occurs and the time is defined as the component shortage time. If the component shortage occurs, the number of components in the next reel is defined as “the remaining number of components that are currently installed in the machine” and the calculation of the formula 1 is performed. The component shortage time is linked to the type of components and defined as the component shortage time data 173D and stored in the storing section 131.

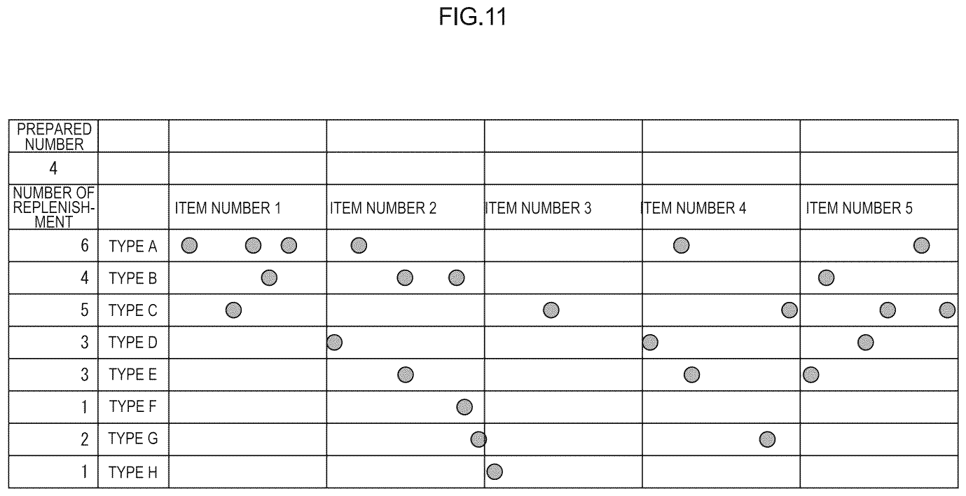

The component shortage time data 137D is calculated for all the substrates (item 1, item 2 . . . ), a component shortage timing chart illustrated in FIG. 11 is created. In the component shortage timing chart, the timing of occurrence of the component shortage is calculated based on the premise that no replenishment is performed. Therefore, to calculate the timing of occurrence of the component shortage based on the premise that the replenishment operation is performed before occurrence of the component shortage, the workable time necessary for the replenishment operation needs to be included in the component shortage timing chart. The workable time that is linked to the type of component is defined as the workable time data 137E and stored in the storing section 131.

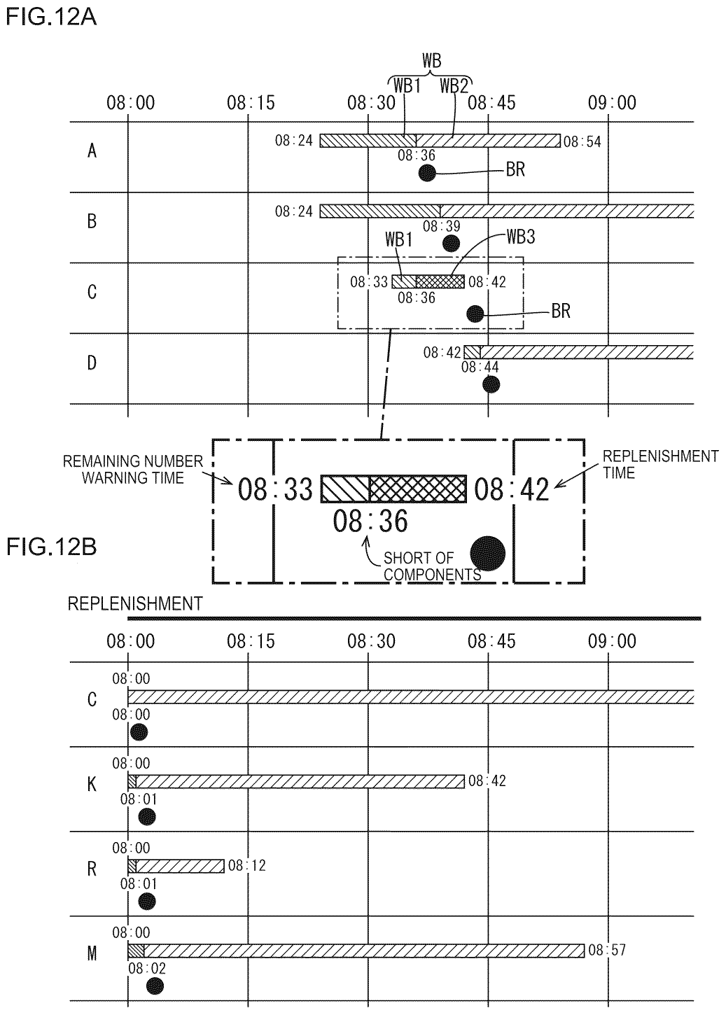

FIG. 12A illustrates simulation performed by the simulator 135 in which the workable time is included in the component shortage timing chart to check whether the component shortage occurs or not. In the drawing, the letters of A, B, C, D . . . represent the types of components, the numbers 08:00, 08:15, 08:30, 08:45, 09:00 . . . on the lateral axis represent the time, the lateral band section WB represents the workable time (time from the warning of the remaining number of components to the component shortage), the left portion (with hatching) WB1 of the lateral band section WB represents the time from the warning of the remaining number of components to the completion of the replenishment operation, the right portion (with hatching) WB2 of the lateral band section WB represents the time from the completion of the replenishment operation to the component shortage with no further replenishment being performed, the right portion (with crossed hatching) WB3 of the lateral band section WB of the component type C represents the time from the component shortage to the completion of the replenishment operation. The black circles BR represent replenishment completion time. As to the component type C, the component shortage occurs at 08:30 and the component replenishment is finished at 08:42 and therefore, the machine stops for six minutes.

The causes of the occurrence of component shortage will be described. In FIG. 12A, the replenishment operation is successively performed and the replenishment operation for the components of the component type C may be delayed. Or the workable time (the time from the warning of the remaining number to the short of the components) may be short. Or the operator may not be available for the replenishment operation for the components of the component type C because the operator performs another operation (other than the replenishment operation). Examples of another operation may be soldering preparation or attending a meeting. The unworkable time that is linked to the type of component is defined as the unworkable time data 137F and stored in the storing section 131. With the unworkable time being inputted to the simulator 135, the simulation can be performed with considering the unworkable time during which the operation cannot be performed.

As illustrated in FIG. 12B, by using an AF for the components of type C in which the component shortage is supposed to occur, the component shortage can be surely avoided. With the time for starting the component mounting operation being 8:00, the replenishment of the components of type C can be performed at the same time as the starting of the mounting operation by installing the AF for the components of type C before starting the mounting operation.

In FIG. 12A, a time period in which the workable times overlap is defined as rush and it is found that the component shortage occurs at the time of rush that requires multiple replenishment operations to be perfomed at the same time. Among the rushes, a time period in which first workable time of the manual feeder 18 whose component shortage is detected by the component shortage detecting section 133 and second workable time of another manual feeder 18 that is continous to the past from the first workable time overlap is defined as a specified rush. The rush is detected by the rush detection section 134. In addition to the components of type C, the components of three types A, B, D are included in the same rush and the AF may be utilized more effectively for the components of some of the types A, B, D than the components of type C. The manual feeders that supply the components of type A, the components of type B, and the components of type D correspond to the manual feeder related to the component shortage in claim 1. The comonent shortage may be avoided by using the AF for any one of the components of type A, the components of type B, and the components of type D.

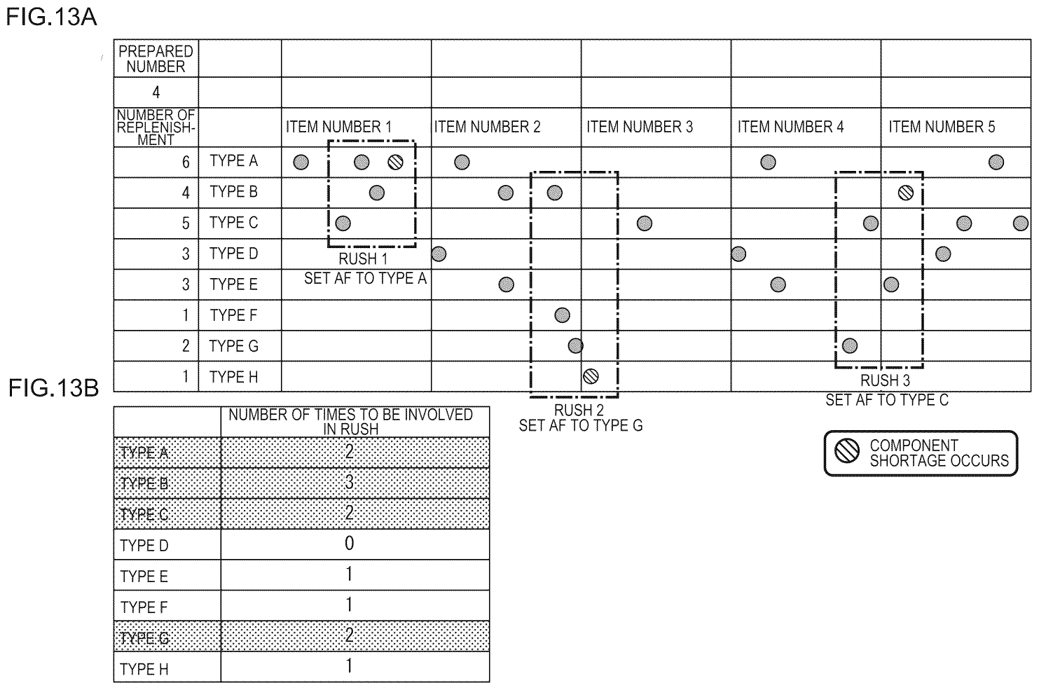

FIG. 13A illustrates a component shortage timing chart in which multiple rushes occur in the production plan of producing the product items 1 to 5. The multiple rushes include a rush 1, a rush 2, a rush 3 in this order from the left of the chart. In FIG. 13A, the rush 1, the rush 2, and the rush 3 are defined as the specified rush. The component shortage occurs in the components of type A in the rush 1, the component shortage occurs in the components of type H in the rush 2, and the component shortage occurs in the components of type B. The AF is effectively used for the components in which the rush occurs with high frequency. Therefore, the AF is used for the component type for which the AF is effectively used. If the effectiveness of using the AF is same among the different types of components, a using speed is considered. The using speed is the number of components to be used per one second (the number of components to be used per one substrate/a tacttime). Extra AFs may be arranged freely. After the AFs are arranged, the simulation may be performed again.

The FIG. 13B illustrates a table indicating the number of times that every type of the components are involved in the rush. The number of times that the components of type B are involved in the rush is three and is greatest. The number of times that the components of types A, C, G are involved in the rush is two and second greatest. As illustrated in FIG. 13A, the number of AFs that are prepared is four and the AFs can be used for the components of types A, B, C, G, respectively. The AF is used for the components of type A in the rush 1, the AF is used for the components of type G in the rush 2, and the AF is used for the components of type C in the rush 3. After the AFs are arranged as described above, the simulation is performed again by the simulator 135 to check whether the component shortage is overcome. If the component shortage is not overcome, the AF may be used for the components in which the component shortage occurs. This may decrease the efficiency; however, the component shortage can be avoided surely.

The machine communication section 136 is an interface and is configurd to transmit and receive signals to and from the component mounting device M1 via the LAN 2.

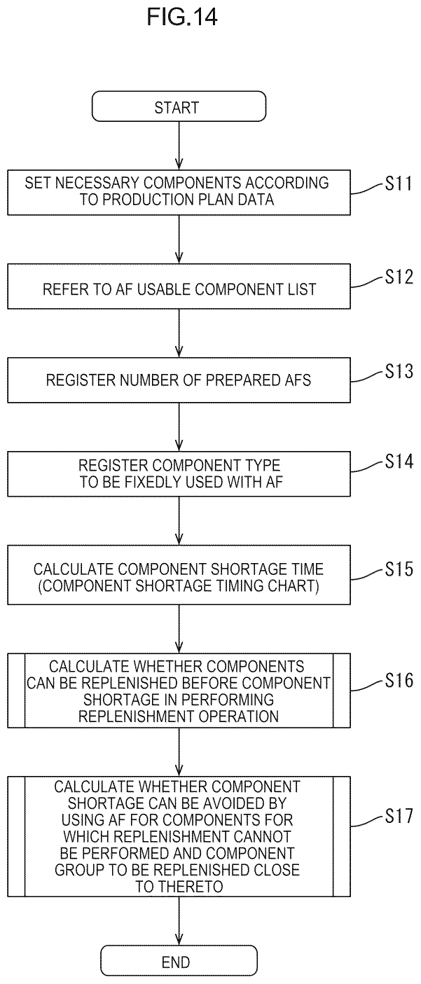

Next, a processing method of the automatic feeder arrangement support system 10 in the component mounting line 1 according to this embodiment will be described with reference to the flowcharts illustrated in FIGS. 14 to 16. The management server 3 stores data from the input section 119 and performs predefined processes. The computer in which the central processing unit (CPU) is installed is connected to the management server 3 and the predefined processes may be performed with the programs installed in the computer.

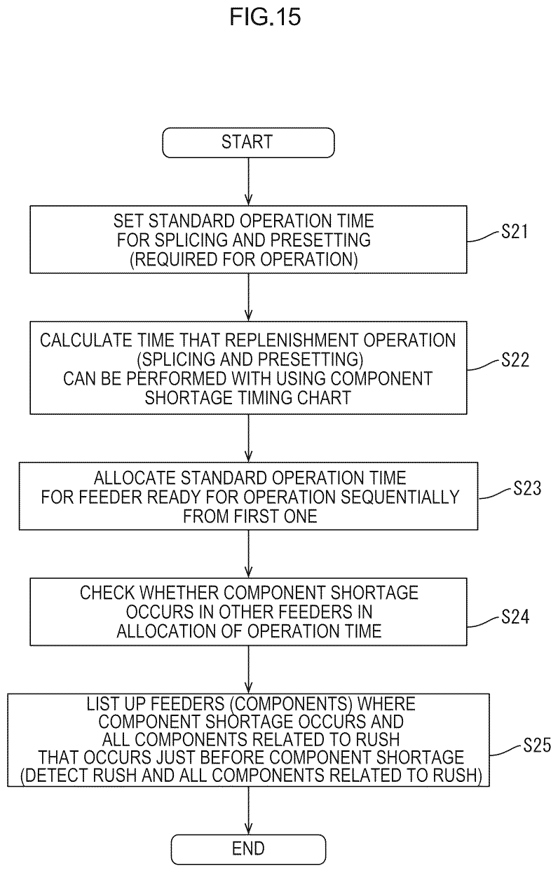

As illustrated in FIG. 14, necessary components are set according to the production plan data 137A (step S11), an AF usable component list is referred to (step S12), the number of prepared AFs is registered (step S13), and the component type to be fixedly used for the AF is registered (step S14). The component shortage timing chart is created by the simulator 135 and the component shortage time is calculated by the component shortage time calculation section 132 (step S15). Next, it is calculated whether the components can be replenished before the component shortage when the replenishment operation is performed (step S16). Details of step S16 will be described with reference to the flowchart in FIG. 15.

As illustrated in FIG. 15, standard operation time for splicing and presetting (time required for the operation) is set (step S21) and the time in which the replenishment operation can be performed (the splicing and presetting) is calculated with using the component shortage timing chart (step S22). Next, the standard operation time is allocated for the manual feeder 18 that is ready for the operation sequentially from the first one (step S23). It is checked whether the component shortage is to occur in other manual feeders 18 at the time of allocation of the operation time (step S24). Next, the rush detection section 134 detects a rush, and the manual feeder 18 (the components E) in which the component shortage occurs and all the components E that are related to the rush that occurs just before the component shortage are detected and a list of the components E is made (the rush and all the components related to the rush are detected) (step S25).

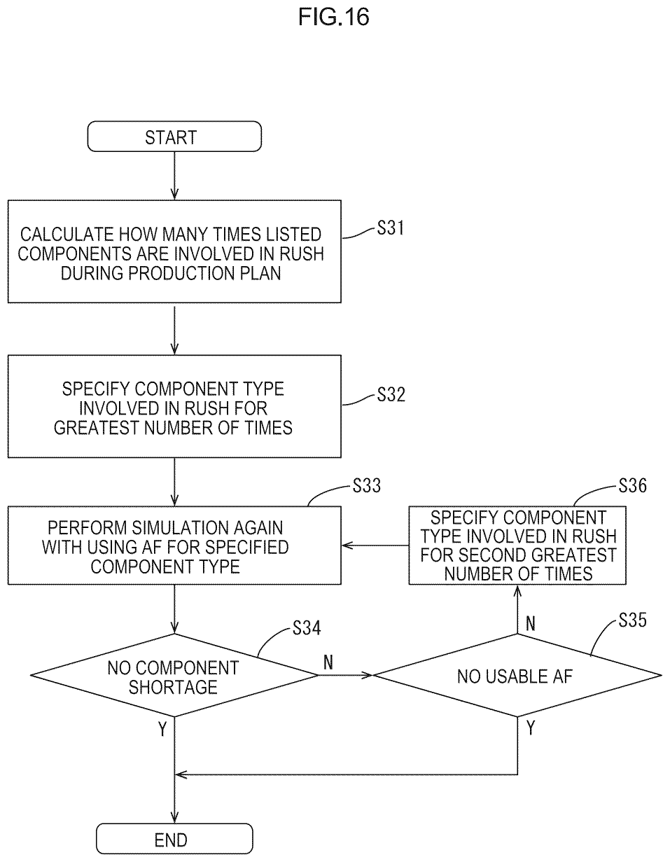

The process returns to FIG. 14 and it is calculated whether the component shortage can be avoided by using the AF for the components E for which the replenishment cannot be performed and the group of components that is to be replenished close thereto (step S17). Details of step S17 will be described with reference to the flowchart in FIG. 16.

As illustrated in FIG. 16, it is calculated how many times the components E (the component types) included in the list will be involved in the rush during the production plan (step S31). One type of the components E (the component types) that is involved in the rush for the greatest number of times is specified (step S32). With using the AF for the specified components E (component type), the simulation is performed again and it is checked by the component shortage detection section 133 whether the component shortage occurs (step S33). As a result, if no component shortage is detected (Y at step S23) the process is terminated.

If it is determined that the component shortage occurs (N at step S34), it is checked whether there is an AF that can be used. If it is determined that there is no AF that can be used (Y at step S35), the process is terminated. If it is determined that there is an AF that can be used (N at step S35), a type of the components E (the component type) that is involved in the rush for the second greatest number of times is specified (step S36). The process returns to step S33 and the AF is used for the components of the specified component type and the simulation is perfomed again by the simulator 135 and it is checked by the component shortage detection section 133 whether the component shortage occurs.

As described above, according to this embodiment, one of the manual feeders 18 is determined as a target that is to be replaced with the automatic feeder 40 such that the component shortage is not detected by the component shortage detection section 133 by replacing the manual feeder 18 with the automatic feeder 40. The automatic feeders 40 are set such that no component shortage is detected. Therefore, the component shortage is previously avoided and the planning of operations, which is a merit of introduction of the automatic feeders 40, can be achieved.

The component shortage time data 137D is calculated by the component shortage time calculation section 132 and the simulation is performed and the component shortage detection section 133 detects whether component shortage occurs or not. If component shortage is detected, the manual feeder 18 is replaced with the automatic feeder 40. Then, the simulation is performed again and the component shortage detection section 133 detects whether component shortage occurs or not.

With the manual feeder 18 in which the component shortage is detected by the component shortage detection section 133 being defined as aa target that is to be replaced with the automatic feeder 40, the component shortage is surely avoided. With the manual feeder 18 that is related to the manual feeder 18 in which the component shortage is detected by the component shortage detection section 133 being defined as a target that is to be replaced with the automatic feeder 40, for example, the automatic feeder 40 can be used for the components that are effective in avoiding the component shortage. With the manual feeder 18 in which the component shortage is detected by the component shortage detection section 133 and the related manual feeder 18 being defined as targets that are to be replaced with the automatic feeders 40, the manual feeders 18 that are to be replaced with the automatic feeders 40 are narrowed to the manual feeder 18 in which the component shortage is detected by the component shortage detection section 133 and the related manual feeder 18.

The time period in which the consecutive workable times overlap in the replenishment operation for the manual feeders 18 or the time period in which the workable time and the time other than the replenishment operation for the manual feeder 18 overlap is defined as the rush. The rush detection section 134 performs simulation and detects whether a rush occurs. The rush detection section 134 can detect a rush related to the manual feeder 18 in which the component shortage is detected by the component shortage detection section 133. Therefore, the arrangement of the automatic feeders 40 can be determined based on the rush.

The manual feeder 18 in which the component shortage is detected by the component shortage detection section 133 and the related manual feeder 18 that is related to the manual feeder 18 in which the component shortage is detected by the component shortage detection section 133 are defined as targets that are to be replaced with the automatic feeder 40. Therefore, the manual feeders 18 that are to be replaced with the automatic feeders 40 can be narrowed to the manual feeder 18 in which the component shortage is detected by the component shortage detection section 133 and the related manual feeder 18.

Other manual feeders 18 that are included in the rush where the manual feeder 18 in which the component shortage is detected by the component shortage detection section 133 is included are defined as targets that are to be replaced with the automatic feeders 40. Thus, the manual feeders 18 that are to be replaced with the automatic feeders 40 can be narrowed to the other manual feeders 18 included in the rush.

When multiple rushes are caused during the production plan, one of the manual feeders 18 that is involved in the rush for the greatest number of times is defined as a target that is to be replaced with the automatic feeder 40. The manual feeder 18 that is involved in the rush for the greatest number of times is determined as the one that is to be replaced with the automatic feeder 40.

A combination of the manual feeders 18 can be determined among the manual feeders 18 that are defined as the ones to be replaced through the process performed by the automatic feeder arrangement support system 10.

By performing the simulation with considering the unworkable time, the rush detection section 134 can detect the rush that causes component shortage with considering the unworkable time.

The manual feeder 18 in which the component shortage is detected by the component shortage detection section 133 may be defined as the one to be replaced with the automatic feeder 40 to surely avoid the component shortage.

### Details of Second Embodiment of the Present Disclosure

An example of an automatic feeder arrangement support system 210 in a component mounting line according to the present disclosure will be described with reference to drawings. The present disclosure is not limited to the embodiment but all modifications within and equivalent to the technical scope of the claimed disclosure may be included in the technical scope of the present technology.

In the first embodiment, after checking the places where the rush occurs based on the whole production plan, the arrangement of the automatic feeders 40 is determined. In the second embodiment, the present arrangement of the automatic feeders 40 is changed with performing the simulation all the time and optimal arrangement is determined.

In the first embodiment, component shortage may not occur if the components are used in multiple lines or the timing is changed due to the short time breakdown (such as errors) during the producing process. Additional component shortage may occur due to the change of the timing.

In the first embodiment, if the number of the automatic feeders 40 is insufficient, the machine stoppage due to component shortage cannot be avoided perfectly. Namely, if the number of prepared AFs is insufficient, the component shortage occurring in the rush may not be obviated. With the plan being changed due to mistakes or errors during the producing process, the replenishment time may be changed and this may increase or decrease the number of rushes. If the plan of using the AF is cancelled, the AF that currently set may be replaced with another feeder to effectively use the AF.

To deal with the above-described situations, in the second embodiment, it is detected whether component shortage occurs during the producing process, that is, component shortage is not checked for the whole production plan. If the component shortage is detected, the process for avoiding the component shortage is performed at any time as appropriate. According to the production progress, the feeder that requires AF is changed. Therefore, the replacing the manual feeder with the AF is instructed as appropriate.

The replacement of the manual feeder with the AF is performed if there is currently a free AF and the replenishment operation is scheduled to be performed for a predefined number of times or greater after the replacement to the AF. The free AF is an AF that is not to be used for the type of products that are being produced. The predefined number of times is two, for example. If component shortage occur by replacing the AF with the manual feeder 18, the AF may not be replaced. With setting the predefined number of times is n and it takes 40 seconds for the replacing operation, n may be set freely so as to satisfy 40 seconds+number of times of presetting n<number of times of splicing n.

If there is no free AF or the replenishment operation is not scheduled to be performed for the predefined number of times or more after replacing the manual feeder with the AF, the replacement to the AF may not be performed because of the following reasons. The machine may be stopped due to mistakes that may be caused at the time of replacement or additional rush may occur if the AF that is being used is moved. As will be described later, if the replacement is not performed, warning is displayed on the display section 118 and the component shortage may be avoided with help from other lines or other works.

If no rush occurs from now on or there is no manual feeder 18 that has priority to be replaced, the determination may be performed based on the using speed (the number of components to be used per one substrate/a tacttime) instead of the rush. Accordingly, the AF is not used for the component type that is not used at all and the AF can be used for the component type in which component shortage does not occur but the replenishment is to be made for the predefined number of times or more.

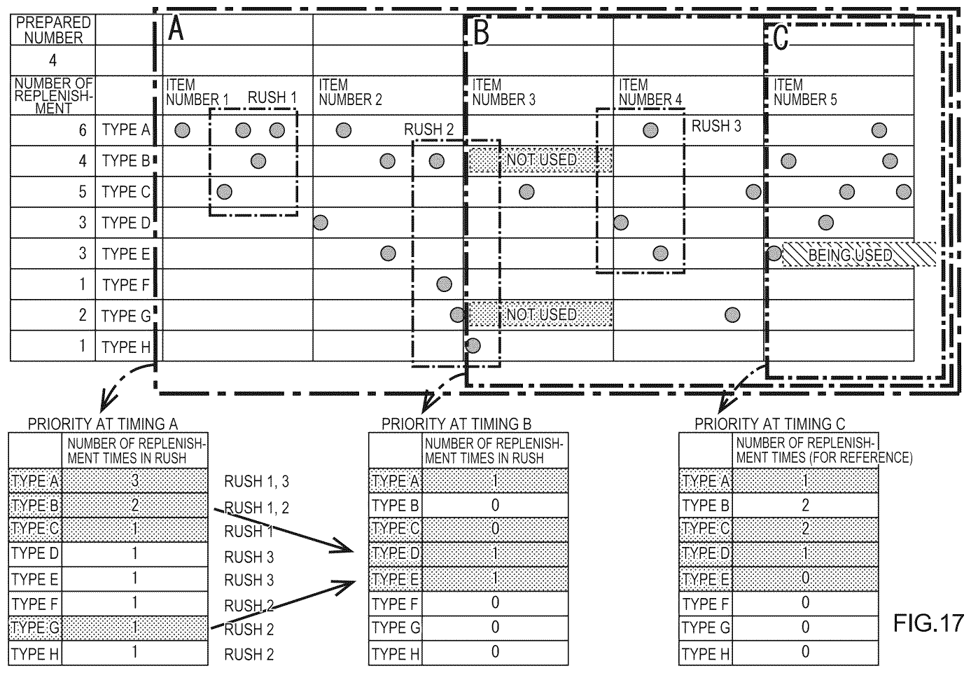

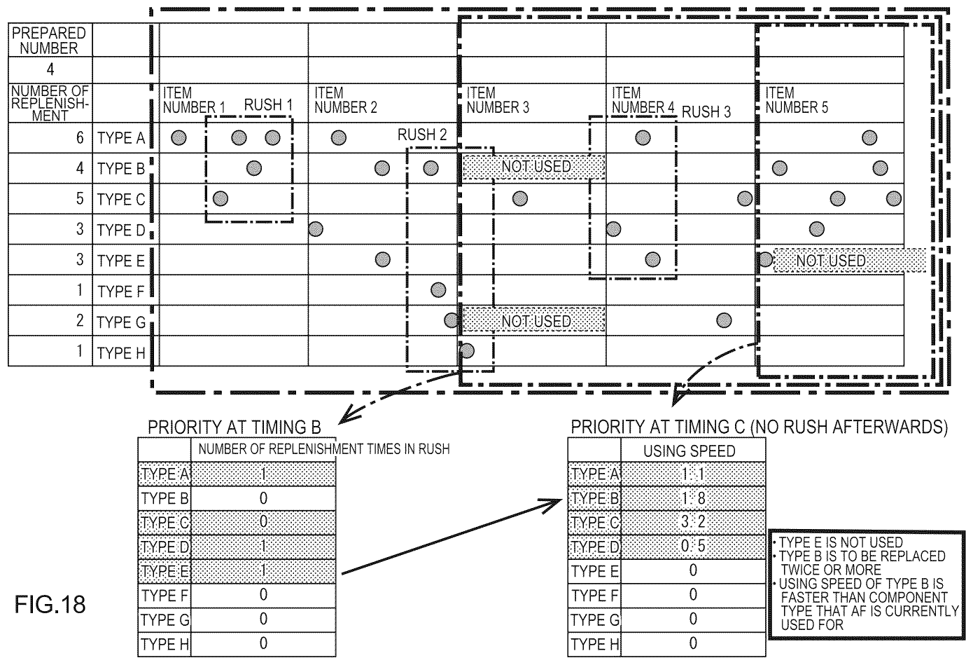

Next, the automatic feeder arrangement support system 210 according to the second embodiment will be described with reference to FIGS. 17 and 18. A, B, and C in the drawings represent production timing. Timing A represents production start timing and timing B and timing C represent timings during the production. Products of item numbers 1, 2, 3, 4, and 5 are produced in this order. The timing A is production start timing of the item number 1, the timing B is production start timing of the item number 3, and the timing C is production start timing of the item number 5.

As illustrated in FIG. 17, the priority at the timing A is determined based on the number of replenishment times in rushes (the number of times that the components are involved in the rush). The number of replenishment times in rushes as to the components of type A is three and greatest, the number of replenishment times in rushes as to the components of type B is two and second greatest, and the number of replenishment times in rushes as to the components of types C to H is one and third greatest. As to the components of types C to H, with dealing with the closest rush, the components of types F, G, and H have higher priority. Furthermore, with considering the using speed, the components of type G have highest priority. Therefore, the AFs are used for the components of types A, B, C, and G. However, the number of AFs included in the system is four. Therefore, AFs are not prepared for the components of types D and E.

As a result of performing the simulation again at the timing B, the closest rush is changed to the rush 3. The priority at the timing B is determined based on the number of replenishment times in rushes (the number of times that the components are involved in the rush). The number of replenishment times in rushes as to the components of types A, D, and E is one and greatest, and the number of replenishment times in rushes as to the components of types B, F, G, and H is zero. The number of replenishment times in the rush 3 as to the components of type B is zero and the components of type B are not used for the item number 3. Therefore, it is suggested to use the AF, which is currently set for the components of type B, for the components of type D. The number of replenishment times in the rush 3 as to the components of type G is zero and the components of type G are not used for the item number 3. It is suggested to use the AF, which is currently set for the components of type G, for the components of type E.

As a result of performing the simulation again at the timing C, no rush is detected. Therefore, the priority at the timing C is maintained as it is. For the item number 5, the number of replenishment times as to the components of type B is two and greatest, the number of replenishment times as to the components of types A and D is one and second greatest, and the number of replenishment times as to the components of types E, F, G, and H is zero.

Next, the schedule as to the components of type E is changed at the timing C and the components of type E are not to be used. In such a case, the priority at the timing C is determined based on the using speed. The using speed as to the components of type C is 3.2 and highest, the using speed as to the components of type B is 1.8 and second highest, the using speed as to the components of type A is 1.1 an third highest, the using speed as to the components of type D is 0.5 and fourth highest, and the using speed as to the components of types E, F, G, and H is zero. It is suggested to use the AF, which is currently used for the components of type E, for the components of type B because of the following reasons. The components of type E are not currently used, replacement of the components of type B is scheduled to be performed two or more times, and the using speed of the components of type B is faster than that of the component type that the AF is currently used for (the components of type E).

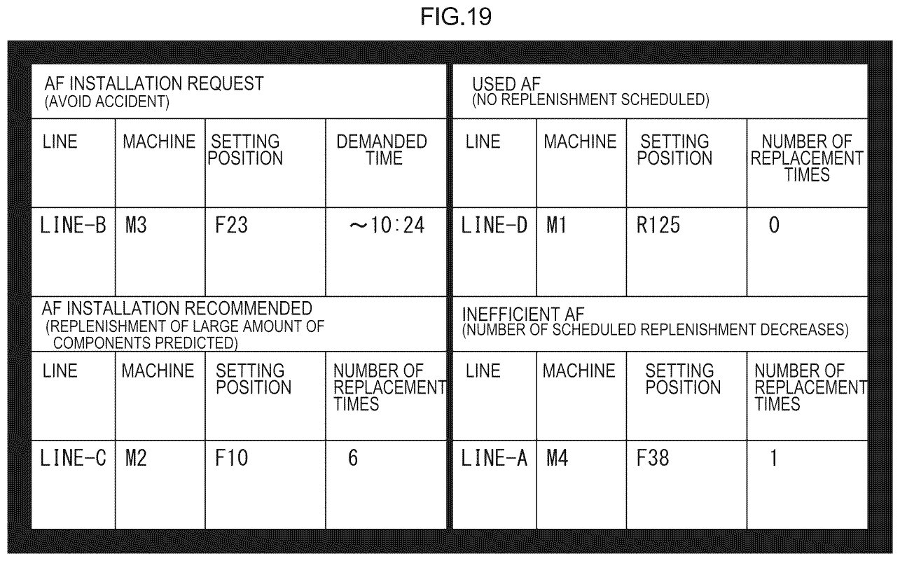

In the second embodiment, the information as illustrated in FIG. 19 is displayed on the display section 118. First, “AF INSTALLATION REQUEST” is an instruction that demands installation of an AF to avoid an accident that is predicted due to component shortage by the simulation when the AF is not currently installed and the accident is predicted. When such an instruction is displayed, the operator must install the AF in the specified position. Here, the instruction informs that the line is LINE-B, the machine is M3, the setting position is F23, the demanded time is before 10:24. That is, the AF needs to be installed before ten twenty four.

Next, “AF INSTALLATION RECOMMENDED” includes information that recommends installation of an AF when the AF is not currently installed and component shortage may not occur but replenishment of a large amount of components is predicted by the simulation. The operator determines whether to install an AF or not. Here, the information includes that the line is LINE-C, the machine is M2, and the setting position is F10, and the number of replacement times is six.

Next, “USED AF” informs that the AF is currently installed and the component replenishment is not scheduled to be performed and the AF may be replaced with another feeder. Information in “USED AF” includes that the line is LINE-D, the machine is M1, the setting position is R125, and the number of replacement times is zero. For example, the automatic feeder 40 that is not replaced yet (the number of replacement times is zero, a setting value of the number of replacement times is 0.5 or smaller) may be defined as the one to be replaced or the automatic feeder 40 whose number of replacement times is one or smaller (the setting value of the number of replacement times is 1 or smaller) may be defined as the one to be replaced.

“INEFFICIENT AF” informs that the AF is currently installed but the number of scheduled component replenishment operations is decreased and the AF may be replaced with another feeder. Information in “INEFFICIENT AF” includes that the line is LINE-A, the machine is M4, the setting position is F38, and the number of replacement times is one.

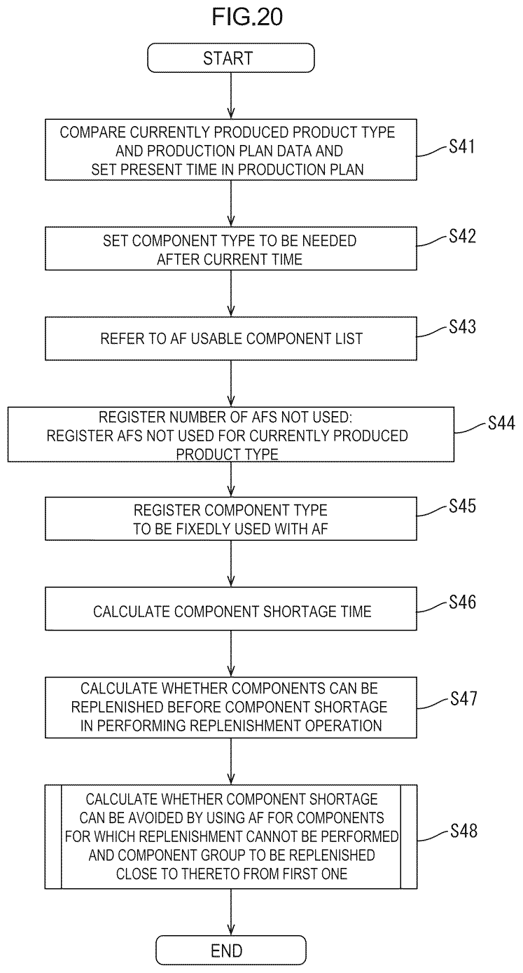

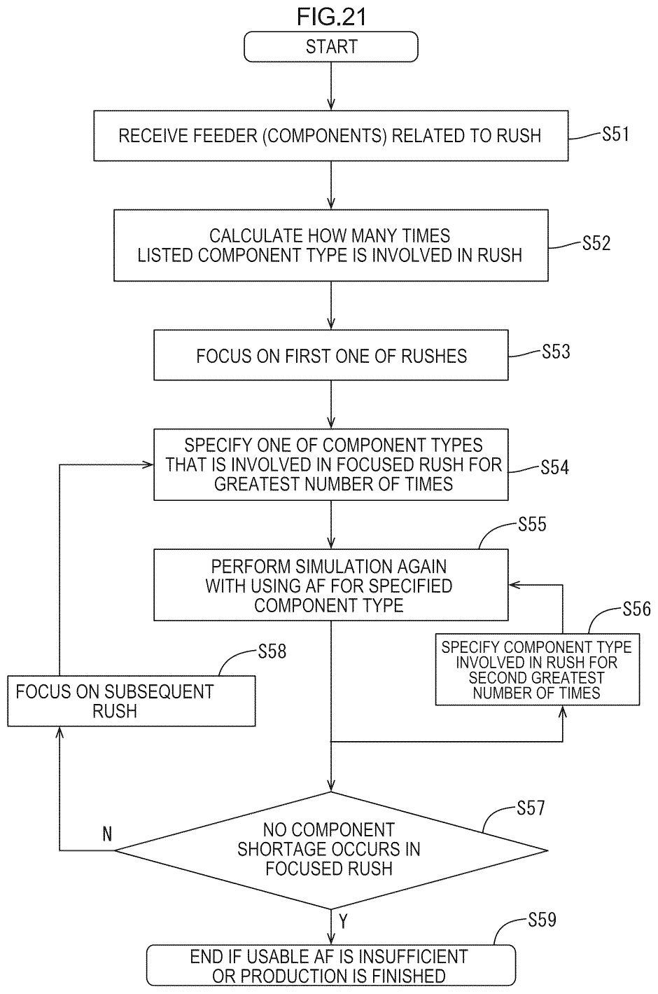

Next, a processing method of the automatic feeder arrangement support system 210 in the component mounting line 1 according to this embodiment will be described with reference to the flowcharts illustrated in FIGS. 20 and 21.

As illustrated in FIG. 20, the product type that is currently produced and the production plan data 137A are compared and the present time in the production plan is set (step S41) and the components E that will be needed after the current time are set (step S42). Next, the AF usable component list is referred to (step S43) and the number of AFs that are not used is registered (step S44). At step S44, the AFs that are not used for the currently produced product type are registered. Next, the components E (component type) for which the AF is to be fixedly used are registered (step S45). The component shortage occurrence timing chart is created by the simulator 135 and the component shortage time is calculated by the component shortage time calculation section 132 (step S46). Next, it is calculated whether the replenishment can be performed before the occurrence of component shortage when the replenishment operation is performed (step S47). Details of the process of step S47 are similar to the process of the flowchart in FIG. 15 and will not be described. It is calculated whether the component shortage can be avoided with using the AFs for the components E (component type) that cannot be replenished and the group of components that are to be replenished close thereto (step S48). Details of step S48 will be described with reference to the flowchart in FIG. 21.

As illustrated in FIG. 21, the manual feeder 18 (the components E) that is related to the rush is received (step S51). Next, it is calculated how many times the components E (component type) that are included in the list are involved in the rush (step S52). The first one of the rushes is focused on (step S53) and one of the types of the components E that are involved in the focused rush for the greatest number of times is specified (step S54). The simulation is performed by the simulator 135 again with an AF being set for the specified components E (component type) and the component shortage detection section 133 determines whether component shortage occurs or not (step S55). If there is another type of the components E that are involved in the focused rush for the second greatest number of times, the other type of the components E is specified (step S56). The process returns to step S55 and the simulation is performed by the simulator 135 again with an AF being set for the specified components E of the other type and the component shortage detection section 133 determines whether component shortage occurs or not.

As a result, if no component shortage occurs in the focused rush (Y at step S57) and usable AFs are insuffcient or the production is finished, the process is terminated (step S59). If component shortage still occurs in the focused rush at step S57 (N at step S57), a subsequent rush is focused on (step S58) and the processes of step S54 and the subsequent steps will be performed.

As described before, according to this embodiment, by displaying the manual feeder 18 that is to be replaced with the automatic feeder 40 on the display section 118, it can be confirmed with the display section 118 which one of the manual feeders 18 is to be replaced.

When the manual feeder 18 that is to be replaced with the automatic feeder 40 is displayed, the due date of the replacement is also displayed on the display section 118.

Accordingly, it can be confirmed with the display section 118 which one of the manual feeders 18 should be replaced and until when the manual feeder 18 should be replaced.

The component shortage detection section 133 obtains information from the component mounting device during the production and periodically performs the simulation to detect whether the component shortage occurs. Therefore, the arrangement of the automatic feeders 40 can be determined according to the actual production condition.

If the scheduled number of using time of the automatic feeder 40 is a setting value or smaller, the automatic feeder 40 is defined as the one to be replaced. Thus, the automatic feeders 40 can be effectively used.

### Details of Third Embodiment of the Present Disclosure

An example of an automatic feeder arrangement support system 310 in a component mounting line according to the present disclosure will be described with reference to drawings. The present disclosure is not limited to the embodiment but all modifications within and equivalent to the technical scope of the claimed disclosure may be included in the technical scope of the present technology.

In the first embodiment, the component shortage timing is calculated suppose that the reel to be set is a new one. However, in this embodiment, the component shortage is predicted based on the number of components in a reel that is to be actually delivered from a storage with reference to the production plan with using data from the component management system such as an automated storage. For example, in the first embodiment, with the number of components in a new reel being 6,000, the simulation is performed suppose that 6,000 components are replenished when the replacement is performed.

However, in the actual production, all the components in the reel are hardly used at the end of the production and the components remain in the reel (the reel is already opened). Some of the reels may include the components that will not be used for a while. In such a case, the reel including the components that are not to be used is removed from the feeder 16 and the remaining number of components in the removed reel is recorded and the removed reel is stored in somewhere. Or the removed reel may be stored in the automated storage.

When producing products of the product type that needs the same type of components included in the removed reel, the reel that is already opened is generally used first. In such a case, the component shortage is likely to be caused more often than using a new reel. If the reel that is to be used is previously determined according to the production plan, it is preferable to perform a simulation with using the remaining number of components included in the previously determined reel.

As an index for selecting a reel in which an AF is set, a priority can be assigned to the reels based on the number of reels that are to be delivered according to the production plan. The logic from the detection of rushes to avoidance of machine stopping due to the component shortage is similar to that of the first and second embodiments. This embodiment differs from the second embodiment in the logic of determining to which one of the reels the extra AF or the AF that is not scheduled to be used is to be set. The priority of the reels to which the AFs are to be set is calculated based on the number of reels scheduled to be delivered instead of the using speed of components, which is used for the calculation in the first and second embodiments.

In the first embodiment, the component shortage timing is calculated based on the production plan data 137A (the types and the number of products that are to be produced are set for each component mounting line), the substrate data 137B (or a component table, the components and the number of components that are used for one substrate), and the machine information 137C (the working condition of the component mounting device, the component that is set in the feeder, the feeder that is to be used, and the remaining number of components). In this embodiment, the component shortage timing is calculated based on a list of component types that are stored in the automated storage (or a list of components that are stored in the component management system) in addition to the production plan data 137A, the substrate data 137B, and the machine information 137C.

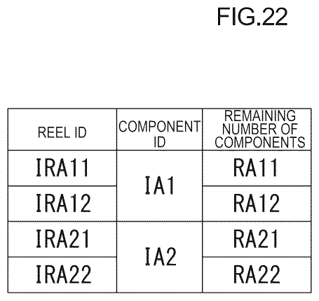

FIG. 22 illustrates a list of components that are stored in the automated storage. The reel whose reel ID is IRA11 includes the components E whose component ID is IA1 and the remaining number of components in the reel IRA11 is RA11. Similarly, the reel whose reel ID is IRA12 includes the components E whose component ID is IA1 and the remaining number of components in the reel IRA12 is RA12. The reel whose reel ID is IRA21 includes the components E whose component ID is IA2 and the remaining number of components in the reel IRA21 is RA21. The reel whose reel ID is IRA22 includes the components E whose component ID is IA2 and the remaining number of components in the reel IRA22 is RA22.

The component shortage time is calculated by the component shortage time calculation section 132 as follows. The number of components used for producing one substrate is subtracting from the remaining number of components that are currently installed in the machine (formula 1). When the remaining number of components becomes insufficient, the component shortage occurs and the current time is defined as the component shortage time. If the component shortage occurs, the calculation is performed according to the formula 1 with using the number of components included in the next reel (using the remaining number of components in the reserved reel) as the remaining number of components that are currently installed in the machine. The component shortage time is stored in the storing section 131 as the component shortage time data 137D.

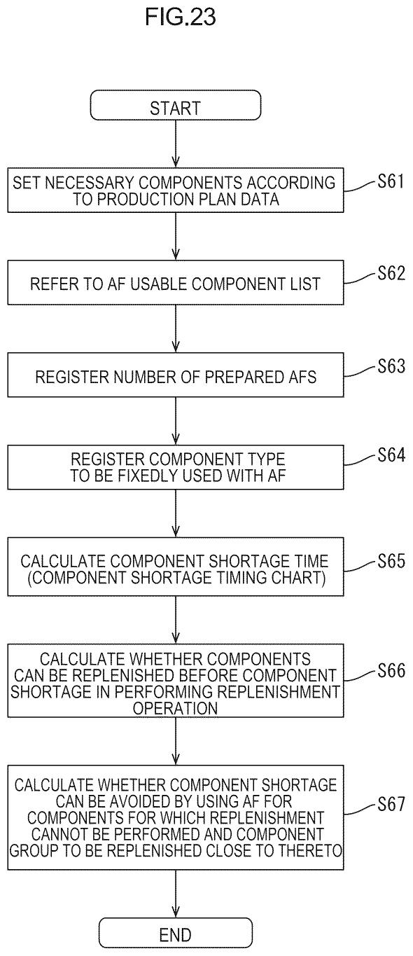

Next, a processing method of the automatic feeder arrangement support system 310 in the component mounting line 1 according to this embodiment will be described with reference to the flowchart illustrated in FIG. 23.

The necessary components are set according to the production plan data 137A (step S61). The AF usable component list is referred to (step S62) and the number of AFs included in the system is registered (step S63). The type of components E for which the AF is to be fixedly set is registered (step S64). Next, in calculating the component shortage time, the remaining number of components included in the reserved reel is used as the number of components to be replenished instead of the full number of components included in a new reel. The component shortage occurrence timing chart is created by the simulator 135 and the component shortage time is calculated by the component shortage time calculation section 132 (step S65). Next, it is calculated whether the replenishment can be performed before the component shortage when the replenishment operation is performed (step S66). It is calculated whether the component shortage can be avoided by using the AFs for the components E that cannot be replenished and the group of components that are to be replenished close thereto (step S67).

According to this embodiment, by performing a simulation with using the actual remaining number of components E at the time of replenishment of the component supply tape, the occurrence of component shortage can be detected according to the actual remaining number of components E.

### Other Embodiments

(1) In the first to third embodiments, the time period in which the workable times overlap is defined as the rush. However, the time period in which the workable time and time for another work (an unexpected work other than the replenishment) overlap may be defined as the rush.

(2) In the first to third embodiments, other manual feeders 18 that are included in the rush where the manual feeder 18 in which the component shortage is detected is included are replaced with the automatic feeders 40. However, other manual feeders 18 that are not included in the rush may be replaced with the automatic feeders 40. For example, the manual feeder 18 that is not included in the rush but includes the components of the same component type as those included in the manual feeder 18 in which the component shortage is detected may be replaced with the automatic feeder 40.

(3) In the first to third embodiments, the manual feeder 18 that is involved in the rush for the greatest number of times is replaced with the automatic feeder 40. However, if the manual feeder 18 that is involved in the rush for the greatest number of times has low using speed or the great remaining number of components, the manual feeder 18 is not to be replaced with an automatic feeder and another manual feeder 18 that is involved in the rush for the second greatest number of times may be a target to be replaced.

(4) In the first to third embodiments, a combination of the manual feeders 18 that are to be replaced with the automatic feeders 40 is determined by performing the simulations repeatedly. However, the manual feeder 18 that is to be replaced with an automatic feeder may be determined at every simulation and the replacement may be performed. Namely, the manual feeder 18 that is to be replaced may be determined only by the first simulation and any simulation may not need to be performed again. The manual feeder 18 that is to be replaced with an automatic feeder 40 may not be necessarily a manual feeder 18 that causes component shortage but may be a manual feeder 18 that is related to the component shortage (for example, the rush) as long as the component shortage can be avoided eventually.

(5) In the first to third embodiments, the simulation is performed with reference to the unworkable time; however, it may be instructed that the operation is performed by another operator during the unworkable time.

(6) In the second embodiment, the manual feeder 18 that is to be replaced is displayed on the display section 118 but it may be informed with sound or light that there is a manual feeder 18 that is to be replaced.

(7) In the second embodiment, information is obtained from the component mounting device during the production and the simulation is periodically performed. However, with the simulation being performed too often, the number of replacement works is increased and the number of rushes may be also increased. Therefore, the simulation may not be performed if the information is not changed, and the simulation may be performed if the information is changed.

What is claimed is:

1. An automatic feeder arrangement support system including a component mounting device that includes automatic feeders and manual feeders including component supply tapes with components respectively, and a mounting head configured to mount the components on a substrate, the automatic feeder arrangement support system comprising:
a component shortage time calculation section configured to calculate component shortage time data based on production plan data and substrate data; and
a component shortage detection section configured to perform a simulation and detect whether component shortage occurs or not based on the component shortage time and workable time data for a replenishment work of the manual feeders, wherein
one of the manual feeders is defined as a target to be replaced with one of the automatic feeders such that component shortage is not detected by the component shortage detection section by replacing the one of the manual feeders with the one of the automatic feeders.

2. The automatic feeder arrangement support system according to claim 1, wherein
when the component shortage detection section detects component shortage, the component shortage detection section performs a simulation again and detect whether component shortage occurs if the one of the manual feeders is replaced with the one of the automatic feeders.

3. The automatic feeder arrangement support system according to claim 1, wherein the one of the manual feeders in which component shortage is detected by the component shortage detection section is defined as a target to be replaced with the one of the automatic feeders.

4. The automatic feeder arrangement support system according to claim 1, wherein another one of the manual feeders that is related to the one of manual feeders in which the component shortage is detected by the component shortage detection section is defined as a target that is to be replaced with another one of the automatic feeders.

5. The automatic feeder arrangement support system according to claim 1, wherein the one of manual feeders in which the component shortage is detected by the component shortage detection section and another one of the manual feeders that is related to the one of manual feeders are defined as targets that are to be replaced with the automatic feeders.

6. The automatic feeder arrangement support system according to claim 4, further comprising a rush detection section configured to perform a simulation and detect whether a rush occurs, wherein
in the replenishment of the manual feeders, a time period in which adjacent workable times overlap or a time period in which workable time and time for a work other than the replenishment of the manual feeders overlap is defined as the rush, and
another one of the manual feeders that is included in the rush including the one of the manual feeders in which component shortage is detected by the component shortage detection section is defined as a target that is to be replaced with another one of the automatic feeders.

7. The automatic feeder arrangement support system according to claim 6, wherein
a continous time period in which the workable time of the one of the manual feeders in which component shortage is detected by the component shortage detecting section and workable time of another one of the manual feeders that is continous to the past from the workable time of the one of the manual feeders overlap is defined as a specified rush,
the rush detection section is configured to detect the specified rush, and
the other one of the manual feeders included in the specified rush is defined as a target to be replaced with another one of the automatic feeders.

8. The automatic feeder arrangement support system according to claim 6, wherein with multiple rushes including the rush being caused during the production plan, one of the manual feeders that is involved in the multiple rushes for a greatest number of times is defined as a target to be replaced with one of the automatic feeders.

9. An automatic feeder arrangement support system, wherein a combination of the manual feeders that are to be replaced with the automatic feeders is determined among the manual feeders that are defined as targets to be replaced by operations repeatedly performed by the automatic feeder arrangement support system according to claim 1.

10. The automatic feeder arrangement support system according to claim 6, further comprising:
a rush detection section configured to perform a simulation and detect whether a rush occurs, wherein
in the replenishment of the manual feeders, a time period in which adjacent workable times overlap or a time period in which workable time and time for a work other than the replenishment of the manual feeders overlap is defined as the rush, and
the rush detection section is configured to perform a simulation with reference to unworkable time and detect whether the rush in which component shortage occurs is caused or not.

11. The automatic feeder arrangement support system according to claim 1, wherein the one of the manual feeders to be replaced with the one of the automatic feeders is displayed on a display section.

12. The automatic feeder arrangement support system according to claim 11, wherein the display section displays the one of the manual feeders to be replaced with the one of the automatic feeders and a due date of replacement.

13. The automatic feeder arrangement support system according to claim 1, wherein the component shortage detection section obtains information from the component mounting device during production and periodically performs a simulation to detect whether component shortage occurs.

14. The automatic feeder arrangement support system according to claim 1, wherein one of the automatic feeders whose number of times to be used is equal to a setting value or smaller is defined as a target to be replaced.

15. The automatic feeder arrangement support system according to claim 1, wherein a simulation is performed with using an actual remaining number of components in the replenishment.

16. A method of supporting arrangement of automatic feeders and manual feeders in a component mounting device that is configured to pick up components from component supply tapes in the feeders and mount the components on substrates, the method comprising:
calculate component shortage time data based on production plan data and substrate data related to the substrates to be produced;
perform a simulation and detect whether component shortage occurs or not based on the component shortage time and workable time data for a replenishment work of the manual feeders; and
define one of the manual feeders as a target to be replaced with one of the automatic feeders such that component shortage does not occur by replacing the one of the manual feeders with the one of the automatic feeders.

17. The automatic feeder arrangement support system according to claim 2, wherein the one of the manual feeders in which component shortage is detected by the component shortage detection section is defined as a target to be replaced with the one of the automatic feeders.

18. The automatic feeder arrangement support system according to claim 2, wherein another one of the manual feeders that is related to the one of manual feeders in which the component shortage is detected by the component shortage detection section is defined as a target that is to be replaced with another one of the automatic feeders.

19. The automatic feeder arrangement support system according to claim 2, wherein the one of manual feeders in which the component shortage is detected by the component shortage detection section and another one of the manual feeders that is related to the one of manual feeders are defined as targets that are to be replaced with the automatic feeders.

20. The automatic feeder arrangement support system according to claim 5, further comprising a rush detection section configured to perform a simulation and detect whether a rush occurs, wherein
in the replenishment of the manual feeders, a time period in which adjacent workable times overlap or a time period in which workable time and time for a work other than the replenishment of the manual feeders overlap is defined as the rush, and
another one of the manual feeders that is included in the rush including the one of the manual feeders in which component shortage is detected by the component shortage detection section is defined as a target that is to be replaced with another one of the automatic feeders.
